(19) United States
(12) Patent Application Publication
(10) Pub. No.: US 2026/0200036 A1
(43) Pub. Date: Jul. 16, 2026

(54) RETAINER RING AND SUBSTRATE HOLDER

(71) Applicant: EBARA CORPORATION, Tokyo (JP)

(72) Inventors: Satoru YAMAKI, Tokyo (JP); Yoshiki NAKAMURA, Tokyo (JP); Shingo TOGASHI, Tokyo (JP); Osamu NABEYA, Tokyo (JP)

(21) Appl. No.: 19/233,943

(22) Filed: Jun. 10, 2025

(30) Foreign Application Priority Data
Jun. 13, 2024 (JP) 2024-095590

(51) Int. Cl. B24B 37/32; B24B 41/06

(52) U.S. Cl. CPC B24B 37/32; B24B 41/06

(57) ABSTRACT

A retainer ring provided in a substrate holder is disclosed, which enables a polishing profile of the substrate in its entirety, including an edge portion of the substrate, to be matched to a desired profile. The retainer ring is used in the substrate holder for pressing the substrate against the polishing pad supplied with the polishing liquid to polish the substrate. The retainer ring has a ring shape, and includes a ring body for supporting an outer periphery of the substrate pressed against the polishing pad. The ring body has at least one ring groove formed in a lower surface to be pressed against the polishing pad and extending concentrically with the ring body, and a barrier for preventing the polishing liquid from reaching an interior from an exterior of the ring body.

### CROSS REFERENCE TO RELATED APPLICATION

This document claims priority to Japanese Patent Application No. 2024-095590 filed Jun. 13, 2024, the entire contents of which are hereby incorporated by reference.

### BACKGROUND

In a manufacturing process of the semiconductor devices, a planarization technique of a surface of the semiconductor device is becoming more important. The most important technique in this planarization technique is chemical mechanical polishing (CMP). This CMP is a process of polishing a substrate, such as a wafer, by placing the substrate in sliding contact with a polishing surface of a polishing pad while supplying a polishing liquid (e.g., slurry) containing abrasive grains, such as silica (SiO2), onto the polishing surface.

A polishing apparatus for performing CMP includes a polishing table that supports the polishing pad having the polishing surface, and a substrate holder for holding the substrate. In such a polishing apparatus, the slurry is supplied onto the polishing pad while the polishing table is rotated together with the polishing pad. The substrate holder presses the substrate against the polishing surface of the polishing pad while rotating the substrate. The substrate is placed into sliding contact with the polishing pad in the presence of slurry, and the surface of the substrate is planarized by a combination of the chemical action of the slurry and the mechanical action of the abrasive grains contained in the slurry.

In order to prevent the substrate from being removed from the substrate holder during polishing of the substrate, the substrate holder has a retainer ring. This retainer ring is arranged so as to surround the substrate, and during polishing of the substrate, the retainer ring is rotated while pressing the polishing pad lying in an outer side of the substrate.

In recent years, there has been a growing demand for more precise control of a film-thickness profile on the substrate (i.e., for improving an in-plane uniformity, which represents a flatness of the substrate surface) due to reasons such as a requirement to respond to various initial film-thickness profiles that may vary depending on semiconductor devices and CMP processes, and a need to improve yield.

However, it is extremely difficult to control a polishing profile in an edge portion of the substrate because of factors such as a high contact pressure between the edge portion of the substrate and the polishing pad, an influence of pad rebound, and an influence of contact between the retainer ring and the edge portion of the substrate. Here, it is possible to control a polishing rate in the edge portion of the substrate by adjusting a pressing force of the retainer ring. However, when the pressing force of the retainer ring is changed, the polishing rate changes in a relatively wide range including not only the edge portion of the substrate but also other regions.

### SUMMARY

Therefore, there is provided a retainer ring that is provided in a substrate holder for matching a polishing profile of the substrate in its entirety, including an edge portion of the substrate, to a desired profile.

Further, a substrate holder is provided that uses such a retainer ring.

Embodiments, which will be described below, relate to a retainer ring which is provided in a substrate holder for polishing a substrate, such as a wafer. Further, the below-described embodiments relate to a substrate holder provided with such a retainer ring.

In one embodiment, there is provided a retainer ring for use in a substrate holder for pressing a substrate against a polishing pad supplied with a polishing liquid to polish the substrate, comprising: a ring body having a ring shape and supporting an outer periphery of the substrate pressed against the polishing pad; wherein the ring body includes: at least one ring groove formed in a lower surface to be pressed against the polishing pad, and extending concentrically with the ring body, and a barrier configured to prevent the polishing liquid from reaching an interior from an exterior of the ring body.

In one embodiment, the barrier is a scraper disposed in the ring groove, and the scraper has a tip end which comes into contact with or is close to the polishing pad when the substrate is polished, and causes the polishing liquid retained in the ring groove to be discharged to an exterior of the retainer ring.

In one embodiment, the barrier is an uneven structure formed in the ring groove, and the uneven structure causes air flow from an inner circumferential surface toward an outer circumferential surface of the ring groove.

In one embodiment, the barrier is an adsorption agent which is disposed in the ring groove, and is capable to absorb the polishing liquid.

In one embodiment, the ring groove comprises a plurality of ring grooves, and the barrier is provided in at least one of the plurality of ring grooves.

In one embodiment, the retainer ring further comprises at least one lateral groove extending from the ring groove to an outer circumferential surface of the ring body.

In one embodiment, there is provided a substrate holder comprising: a head body configured to hold a substrate, and press the substrate against a polishing pad to polish the substrate; and a retainer ring according to any one of claims 1 to 6, the retainer ring being arranged so as to surround the substrate held in the head body.

A combination of the ring groove and the barrier provided in the retainer ring enables an amount of polishing liquid reaching the pad-outer-peripheral-side polishing region of the polishing head, which is a polishing region of the polishing head near an outer periphery of the polishing pad, to be significantly reduced. As a result, the polishing rate of the edge portion of the substrate can be made to be the same as the polishing rate of other portions of the substrate, so that the in-plane uniformity of the entire substrate after polishing can be improved.

### BRIEF DESCRIPTION OF THE DRAWINGS

FIG. 1 is a schematic view showing a polishing apparatus according to an embodiment;

FIG. 2 is a cross-sectional view schematically showing a polishing head according to an embodiment;

FIG. 3 is a schematic view illustrating a region close to a periphery of the polishing pad when a wafer is being polished;

FIG. 4A is a horizontal cross-sectional view schematically showing a retainer ring according to an embodiment, and FIG. 4B is a vertical cross-sectional view schematically showing the retainer ring shown in FIG. 4A;

FIG. 5A is an exploded view schematically showing the retainer ring according to another embodiment, and FIG. 5B is a horizontal cross-sectional view showing a part of the retainer ring shown in FIG. 5A;

FIGS. 6A to 6C are exploded views each showing a modified example of the uneven structure;

FIG. 7A is a horizontal cross-sectional view schematically showing the retainer ring according to still another embodiment, and FIG. 7B is a vertical cross-sectional view schematically showing the retainer ring shown in FIG. 7A;

FIG. 8 is a horizontal cross-sectional view schematically showing a part of the retainer ring according to still another embodiment; and

FIG. 9A is a horizontal cross-sectional view schematically showing a part of a modified example of the retainer ring shown in FIG. 4A, and FIG. 9B is a horizontal cross-sectional view schematically showing a part of a modified example of the retainer ring shown in FIG. 8.

### DESCRIPTION OF EMBODIMENTS

Hereinafter, embodiments will be described with reference to the drawings.

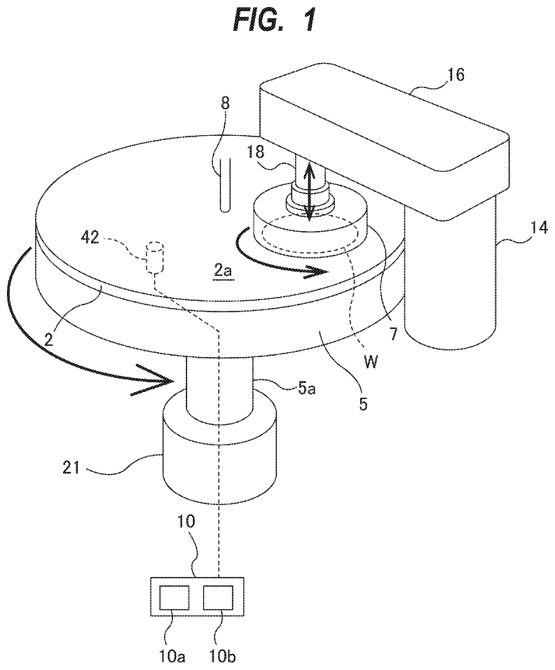

FIG. 1 is a schematic view showing a polishing apparatus according to an embodiment. The polishing apparatus shown in FIG. 1 serves as an apparatus for chemically and mechanically polishing a wafer W, which is an example of a substrate. As shown in FIG. 1, this polishing apparatus includes a polishing table 5 configured to support a polishing pad 2 having a polishing surface 2a, a substrate holder 7 configured to press the wafer W against the polishing surface 2a, a polishing-liquid supply nozzle 8 configured to supply a polishing liquid (e.g., slurry in which abrasive grains are contained) onto the polishing surface 2a, and a controller 10 configured to control at least operation of the substrate holder 7. The substrate holder 7 is also referred to as a polishing head or a top ring, and is configured to hold the wafer W on a lower surface thereof. Hereinafter, the substrate holder 7 is referred to as a “polishing head 7”.

The controller 10 is composed of at least one computer. The controller 10 includes a memory 10a storing programs therein, and an arithmetic device 10b configured to perform arithmetic operations according to instructions included in the programs. The memory 10a includes a main memory, such as random-access memory (RAM), and an auxiliary memory, such as a hard disk drive (HDD) or a solid-state drive (SSD). Examples of the arithmetic device 10b may include a CPU (central processing unit) and a GPU (graphic processing unit). However, the specific configurations of the controller 10 are not limited to these examples. In this embodiment, the controller 10 is configured to control operations of the polishing apparatus in its entirety.

The polishing apparatus further includes a support shaft 14, a polishing-head swing arm 16 coupled to an upper end of the support shaft 14, and a polishing-head shaft 18 rotatably supported by a free end of the polishing-head swing arm 16. The polishing head 7 is fixed to a lower end of the polishing-head shaft 18. A polishing-head rotating mechanism (not shown), which includes an electric motor and the like, is disposed in the polishing-head swing arm 16. This polishing-head rotating mechanism is coupled to the polishing-head shaft 18, and is configured to rotate the polishing-head shaft 18 and the polishing head 7 in a direction indicated by arrow.

The polishing-head shaft 18 is coupled to a polishing-head elevating mechanism (e.g., including a ball screw mechanism and the like), which is not shown in the drawings. This polishing-head elevating mechanism is configured to move the polishing-head shaft 18 vertically relative to the polishing-head swing arm 16. This vertical movement of the polishing-head shaft 18 allows the polishing head 7 to move vertically relative to the polishing-head swing arm 16 and the polishing table 5 as indicated by arrow.

The polishing apparatus further includes a table rotation motor 21 that rotates the polishing pad 2 and the polishing table 5 about their axes. The table rotation motor 21 is disposed below the polishing table 5, and the polishing table 5 is coupled to the table rotation motor 21 through a table shaft 5a. The polishing table 5 and the polishing pad 2 are configured to be rotated by the table rotation motor 21 about the table shaft 5a in a direction indicated by arrow. The polishing pad 2 is attached to an upper surface of the polishing table 5. An exposed surface of the polishing pad 2 is used as the polishing surface 2a for polishing the wafer W. The polishing surface 2a of the polishing pad 2 in its entirety may have grid-shaped and/or ring-shaped grooves formed thereon.

Polishing of the wafer W is performed as follows. The wafer W is held by the polishing head 7 with its surface to be polished facing downward. While the polishing head 7 and the polishing table 5 are being rotated, the polishing liquid (for example, slurry in which abrasive grains are contained) is supplied onto the polishing surface 2a of the polishing pad 2 from the polishing-liquid supply nozzle 8 provided above the polishing table 5. The polishing pad 2 rotates integrally with the polishing table 5 about its central axis. The polishing head 7 is moved to a predetermined height by the polishing-head elevating mechanism (not shown). Further, the polishing head 7 presses the wafer W against the polishing surface 2a of the polishing pad 2 while being maintained at the predetermined height. The wafer W rotates together with the polishing head 7. In a state in which the polishing liquid is present in the polishing surface 2a of the polishing pad 2, the wafer W is brought into sliding contact with the polishing surface 2a. When the polishing surface 2a has the grid-shaped and/or ring-shaped grooves formed thereon, the polishing liquid that has entered into the grooves is used for polishing the wafer W, and thus the wafer W is efficiently polished. A surface of the wafer W is polished by a combination of a chemical action of the polishing liquid and a mechanical action of the abrasive grains contained in the polishing liquid and/or the polishing pad 2.

In this embodiment, the polishing apparatus includes a film-thickness sensor 42 for measuring a film thickness of the wafer W on the polishing surface 2a. The film-thickness sensor 42 is configured to generate a polishing index value that directly or indirectly indicates the film thickness of the wafer W. This polishing index value varies depending on the film thickness of wafer W, and therefore indicates the film thickness of the wafer W. The polishing index value may be a value representing the film thickness itself of the wafer W, or a physical quantity or signal value before being converted to the film thickness.

Examples of the film-thickness sensor 42 may include an optical film-thickness sensor and an eddy current sensor. The optical film-thickness sensor is configured to irradiate the surface of the wafer W with light and determine the film thickness of the wafer W from a spectrum of light reflected from the wafer W. The eddy current sensor is configured to induce an eddy current in a conductive film formed on the wafer W and output a signal value that varies in accordance with impedance of an electrical circuit including the conductive film and a coil of the eddy current sensor. As the optical film-thickness sensor and the eddy current sensor, known devices may be used.

The film-thickness sensor 42 is placed inside the polishing table 5, and rotates integrally with the polishing table 5. More specifically, the film-thickness sensor 42 is configured to measure the film thickness at a plurality of measurement points on the wafer W while traversing across the polishing surface 2a each time the polishing table 5 makes one rotation. In this embodiment, the film-thickness sensor 42 is disposed so as to measure the film thickness at the plurality of measurement points including a center of the wafer W. Therefore, the plurality of measurement points is arranged in a radial direction of the wafer W.

The film-thickness sensor 42 is coupled to the controller 10. The measurement values of the film thickness generated by the film-thickness sensor 42 are monitored by the controller 10. Specifically, the measurement values of the film thickness at the plurality of measurement points on the wafer W are output from the film-thickness sensor 42, sent to the controller 10, and stored in the memory device 10a. The controller 10 creates a film thickness profile of the wafer W based on the measurement values of the film thickness. The film thickness profile represents a distribution of the film thickness along a radial direction of the wafer W.

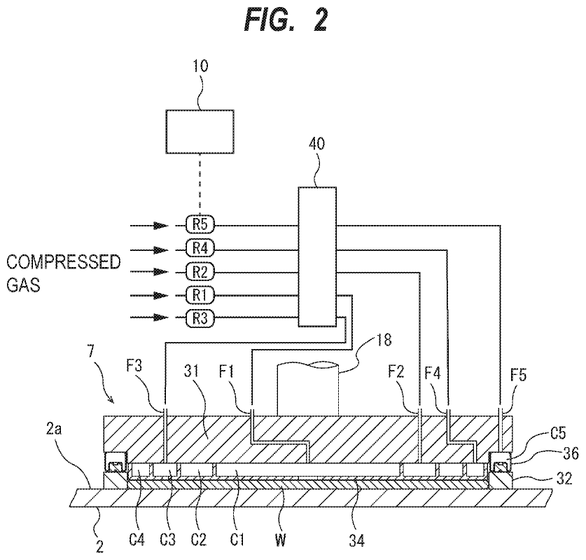

Next, the polishing head 7 will be described below. FIG. 2 is a cross-sectional view schematically showing the polishing head according to an embodiment. The polishing head 7 includes a head body 31 fixed to an end portion of the polishing-head shaft 18, an elastic membrane 34 attached to a lower portion of the head body 61, and a retainer ring 32 disposed below the head body 61. The retainer ring 32 is disposed around the elastic membrane 34. This retainer ring 32 is a ring-shaped structure that holds the outer periphery of the wafer W to prevent the wafer W from being removed from the polishing head 7 during polishing of the wafer W.

Four pressure chambers C1, C2, C3, and C4 are provided between the elastic membrane 34 and the head body 31. The pressure chambers C1, C2, C3, and C4 are formed by the elastic membrane 34 and the head body 31. The pressure chamber C1 in the center has a circular shape, while the other pressure chambers C2, C3, and C4 have a ring shape, respectively. These pressure chambers C1, C2, C3, and C4 are arranged concentrically.

Gas transfer lines F1, F2, F3, and F4 are coupled to the pressure chambers C1, C2, C3, and C4, respectively. One ends of the gas transfer lines F1, F2, F3, and F4 are coupled to a compressed-gas supply (not shown) serving as a utility provided in a factory in which the polishing apparatus is installed. Compressed gas, such as compressed air, is supplied to the pressure chambers C1, C2, C3, and C4 through the gas transfer lines F1, F2, F3, and F4. The compressed gas in the pressure chambers C1, C2, C3, and C4 causes the wafer W to be pressed against the polishing surface 2a of the polishing pad 2 through the elastic membrane 34.

The gas transfer line F3 communicating with the pressure chamber C3 is coupled to a vacuum line (not shown) so that a vacuum can be formed in the pressure chamber C3. A portion of the elastic membrane 34 constituting the pressure chamber C3 has an opening formed therein, and the wafer W is sucked and held by the polishing head 7 by forming a vacuum in the pressure chamber C3. Further, when the compressed gas is supplied to the pressure chamber C3, the wafer W is released from the polishing head 7.

An annular elastic membrane 36 is disposed between the head body 31 and the retainer ring 32, and a pressure chamber C5 is formed inside the elastic membrane 36. The pressure chamber C5 is coupled to the compressed-gas supply source through a gas transfer line F5. The compressed gas is supplied into the pressure chamber C5 through the gas transfer line F5, and the compressed gas in the pressure chamber C5 causes the retainer ring 32 to be pressed against the polishing pad 2.

The gas transfer lines F1, F2, F3, F4, and F5 extend through a rotary joint 70 attached to the polishing-head shaft 18. The gas transfer lines F1, F2, F3, F4, and F5 communicating with the pressure chambers C1, C2, C3, C4, and C5, respectively are provided with pressure regulators R1, R2, R3, R4, and R5. The compressed gas from the compressed-gas supply source is independently supplied into the pressure chambers C1 to C5 through the pressure regulators R1 to R5. The pressure regulators R1 to R5 are configured to regulate pressures of the compressed gas in the pressure chambers C1 to C5, respectively.

The pressure regulators R1 to R5 can change internal pressures of the pressure chambers C1 to C5 independently from each other, and thus, pressing pressures against four corresponding regions of the wafer W, that is, a central portion, an inner intermediate portion, an outer intermediate portion, and an edge portion thereof, and a pressing pressure of the retainer ring 32 against the polishing pad 2 can be regulated independently. The gas transfer lines F1, F2, F3, F4, and F5 are also coupled to air release valves (not shown) so that the pressure chambers C1 to C5 can be opened to the atmosphere. In the present embodiment, the elastic membrane 34 forms the four pressure chambers C1 to C4, but in one embodiment, the elastic membrane 34 may form three or less, or five or more pressure chambers. Only a single pressure chamber may be provided.

The pressure regulators R1 to R5 are coupled to the controller 10. The controller 10 receives the measurement values of the film thickness in the wafer W from the film-thickness sensor 42 (see FIG. 1), determines target pressure values for each of the pressure chambers C1 to C5 based on the measurement values of the film thickness so as to achieve a target film-thickness profile, and sends the target pressure values to the pressure regulators R1 to R5. The pressure regulators R1 to R5 operate to maintain the pressures in the pressure chambers C1 to C5 at the corresponding target pressure values.

The polishing head 7 can apply independent pressures to a plurality of regions in the wafer W. For example, the polishing head 7 can press different regions in the surface of the wafer W against the polishing surface 2a of the polishing pad 2 with different pressures. Accordingly, the polishing head 7 can control a film thickness profile of the wafer W to achieve the target film-thickness profile.

As described above, it is extremely difficult to control the polishing profile in the edge portion of the wafer W because of factors, such as the high contact pressure between the edge portion of the wafer W and the polishing pad 2, the influence of pad rebound, and the influence of contact between the retainer ring 32 and the edge portion of the wafer W. Further, when the pressing force of the retainer ring 32 against the polishing pad 2 is changed to intend to control the polishing rate in the edge portion of the wafer W, the polishing rate of the wafer W changes not only in the edge portion of the wafer W but also in a relatively wide range including other regions.

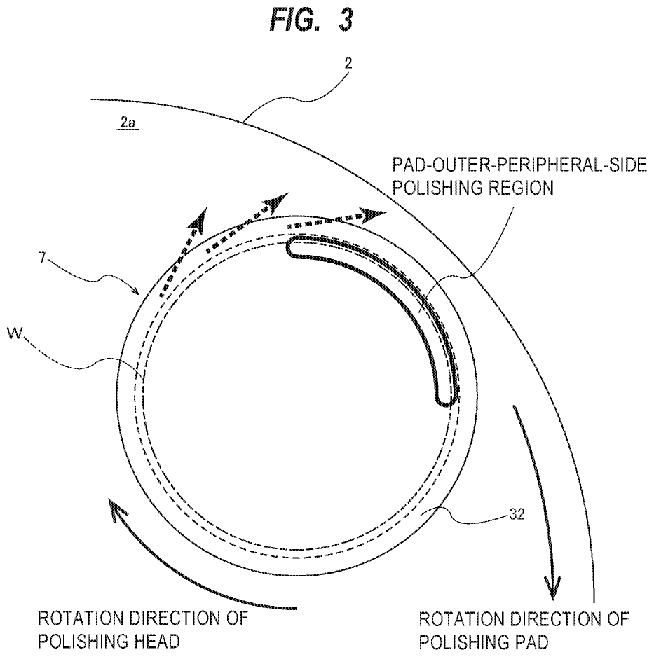

The inventors have studied changes in the polishing rate over the entire surface of the wafer W, and as a result of intensive research, the inventors have found that the polishing rate in the edge portion of the wafer W that is polished in a region of the polishing head 7 close to the outer periphery of the polishing pad 2 is higher than the polishing rate in the edge portion of the wafer W that is polished in other regions. FIG. 3 is a schematic view illustrating a polishing region of the polishing head 7 close to a periphery of the polishing pad 2 when the wafer is being polished. As shown in FIG. 3, when the rotating polishing head 7 presses the wafer W against the rotating polishing pad 2 to polish the wafer W, the polishing rate in the edge portion of the wafer W at the region of the polishing head 7 (see a thick line in FIG. 3) close to the periphery of the polishing pad 2 is higher than the polishing rate in the edge portion of the wafer W at other regions of the polishing head 7. In this specification, the polishing region of the wafer W in the polishing head 7 enclosed by the thick line illustrated in FIG. 3 is referred to as the “pad-outer-peripheral-side polishing region”.

Accordingly, the inventors found that it is possible to improve the in-plane uniformity of the wafer W in its entirety, including the edge portion of the wafer W, by reducing (or controlling) an amount of the polishing liquid reaching the pad-outer-peripheral-side polishing region of the rotating polishing head 7, thereby intentionally reducing the polishing rate of the edge portion of the wafer W in the pad-outer-peripheral-side polishing region of the polishing head 7. Hereinafter, configurations for reducing the amount of polishing liquid reaching the pad-outer-peripheral-side polishing region of the polishing head 7 will be described. To achieve this aim, the retainer ring 32 of the polishing head 7 is provided with a barrier for preventing the polishing liquid (e.g., slurry) from reaching the pad-outer-peripheral-side polishing region of the polishing head 7.

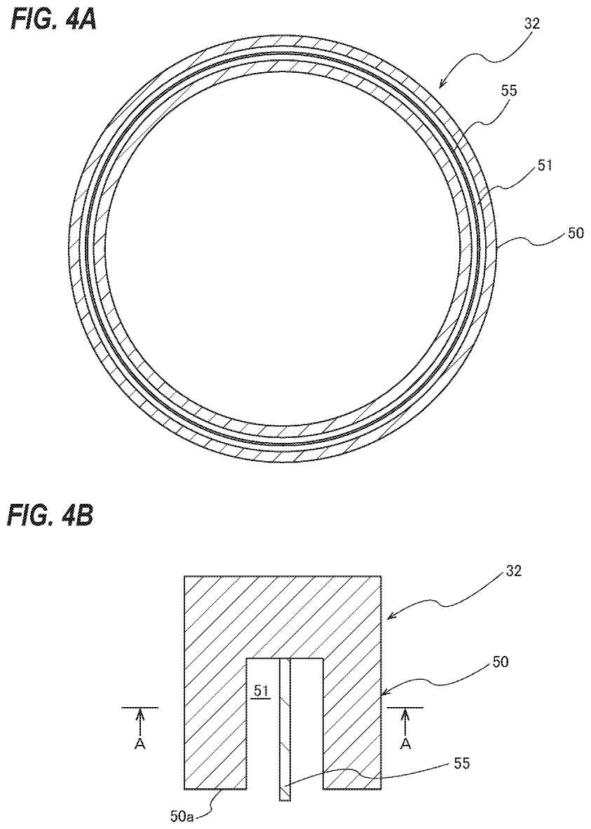

FIG. 4A is a horizontal cross-sectional view schematically showing a retainer ring according to an embodiment, and FIG. 4B is a vertical cross-sectional view schematically showing the retainer ring shown in FIG. 4A. FIG. 4A corresponds to a sectional view taken along line A-A in FIG. 4B. As shown in FIG. 4A and FIG. 4B, the retainer ring 32 has a ring body 50 having a ring shape. The ring body 50 has a lower surface 50a that is pressed against the polishing surface 2a of the polishing pad 2 during polishing of the wafer W, and the lower surface 50a extends in an annular shaped manner. The outer periphery of the wafer W during polishing is held by an inner circumferential surface of the ring body 50, and as a result, the wafer W during polishing is prevented from being removed from the polishing head 7.

Further, the ring body 50 has a ring groove 51 formed in the lower surface 50a, and extending in an annular shaped manner. The ring groove 51 is formed in the lower surface 50a of the ring body 50 concentrically with the ring body 50.

The retainer ring 32 further has a scraper 55 disposed in the ring groove 51. The scraper 55 prevents the polishing liquid (e.g., slurry) supplied from the polishing-liquid supply nozzle 8 onto the polishing surface 2a of the polishing pad 2 from reaching an interior from an exterior of the ring body 50 in the retainer ring 32. In other words, in this embodiment, the scraper 55 serves as a barrier that prevents the polishing liquid from reaching the pad-outer-peripheral-side polishing region (see the thick line in FIG. 3) of the polishing head 7.

The scraper 55 shown in FIG. 4A and FIG. 4B extends from a top surface (upper surface) of the ring groove 51 toward the polishing pad 2. In this embodiment, a tip end (lower end) of the scraper 55 protrudes beyond the lower surface 50a of the ring body 50 in the retainer ring 32, and when the polishing head 7 is brought into contact with the polishing surface 2a of the polishing pad 2, the tip end of the scraper 55 also comes into contact with the polishing surface 2a of the polishing pad 2. Therefore, the scraper 55 should have elasticity sufficient to deform under the pressure applied by the polishing head 7 to the polishing pad 2 during polishing of the wafer W. Since the retainer ring 32 is worn away by polishing of the wafer W, it is desirable that the scraper 55 also have a hardness similar to that of the retainer ring 32. Examples of materials constituting the scraper 55 may include rubber and resin having appropriate elasticity and hardness.

During polishing of the wafer W, the polishing liquid attempting to enter the interior of the retainer ring 32 from the exterior of the rotating polishing head 7 is temporarily accommodated in the ring groove 51 formed in the lower surface 50a of the ring body 50. As a result, the polishing liquid is prevented from reaching the interior of the retainer ring 32 (i.e., the wafer W). In other words, the ring groove 51 serves as a buffer that prevents the polishing liquid flowing in the exterior of the retainer ring 32 on the polishing surface 2a of the rotating polishing pad 2 from entering the interior of the retainer ring 32 (i.e., reaching the wafer W).

Further, the scraper 55 disposed in the ring grooves 51 further prevent the polishing liquid from reaching the interior of the retainer ring 32. More specifically, centrifugal force generated by the rotating polishing head 7 acts on the polishing liquid temporarily retained in the ring groove 51, and thus at least a part of the polishing liquid flowing in the ring groove 51 under the effect of the centrifugal force is discharged (or flows out) toward the exterior of the retainer ring 32 before reaching the wafer W. Further, as shown by the dotted arrow in FIG. 3, the scraper 55 causes most of the polishing liquid retained in the ring groove 51 to be discharged toward the exterior of the retainer ring 32 before reaching the pad-outer-peripheral-side polishing region, so that the amount of polishing liquid reaching the pad-outer-peripheral-side polishing region can be further reduced.

The tip end of the scraper 55 shown in FIG. 4A and FIG. 4B protrudes downward beyond the lower surface of the retainer ring 32, but configuration of the scraper 55 is not limited to this embodiment. As long as the scraper 55 can cause at least a part of the polishing liquid retained in the ring groove 51 to be discharged toward the exterior of the retainer ring 32 before reaching the pad-outer-peripheral-side polishing region, the tip end of the scraper 55 need not protrude beyond the lower surface of the retainer ring 32. In other words, the scraper 55 in its entirety may be accommodated within the ring groove 51. In this case, when polishing the wafer W, the tip end of the scraper 55 is close to the polishing surface 2a of the polishing pad 2. According to the embodiment in which the scraper 55 in its entirety is accommodated within the ring groove 51, the scraper 55 is not worn (abraded) during polishing of the wafer W, so that the wafer W is not scratched by wear particles and/or debris from the scraper 55.

According to this embodiment, a combination of the ring groove 51 and the scraper 55, which serves as the barrier, enables the amount of polishing liquid reaching the pad-outer-peripheral-side polishing region to be significantly reduced. As a result, the polishing rate of the edge portion of the wafer W in the pad-outer-peripheral-side polishing region can be reduced (or controlled). According to experiments conducted by the inventors using the polishing head 7 having the retainer ring 32 shown in FIG. 4A and FIG. 4B, the polishing rate of the edge portion of the wafer W in the pad-outer-peripheral-side polishing region could be controlled to be a value equivalent to the polishing rate near the center of the wafer W. As a result, it has been confirmed that the in-plane uniformity of the wafer W after polishing can be improved.

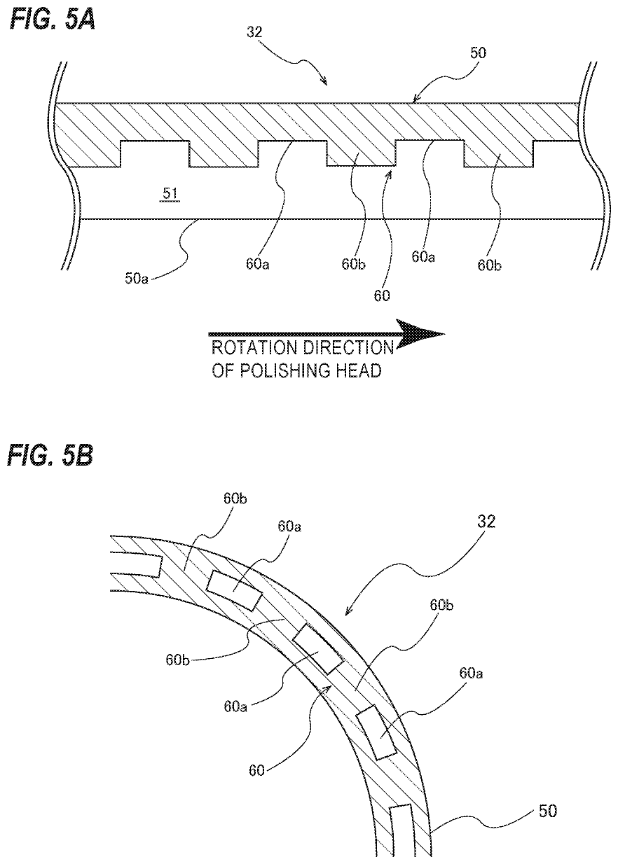

FIG. 5A is an exploded view schematically showing the retainer ring according to another embodiment, and FIG. 5B is a horizontal cross-sectional view showing a part of the retainer ring shown in FIG. 5A. The exploded view shown in FIG. 5A corresponds to a planar exploded view of a vertical section taken along a circumferential direction of the retainer ring having the annular shape. Configurations of this embodiment, which will not be particularly described, are the same as those of the embodiments described with reference to FIGS. 4A and 4B, and redundant descriptions thereof will be omitted.

In the embodiment shown in FIG. 5A and FIG. 5B, the retainer ring 32 has an uneven structure 60 formed in the ring groove 51 as a barrier, instead of the scraper 55. In this embodiment, the uneven structure 60 is formed in the top surface of the ring groove 51, and has concave portions 60a and convex portions 60b protruding downward which are alternately arranged in a circumferential direction of the ring groove 51. Therefore, when the polishing head 7 is pressed against the polishing pad 2 to polish the wafer W, the convex portion 60b is directed toward the polishing surface 2a of the polishing pad 2. In addition, as shown in FIG. 5B, the convex portion 60b expands radially along a radial direction of the retainer ring 32, and thus a width (size) of the convex portion 60b in a horizontal direction expands from an inner circumferential surface toward an outer circumferential surface of the ring groove 51.

When the retainer ring 32 is rotated, the uneven structure 60 causes air flow in the ring groove 51 from the inner circumferential surface toward the outer circumferential surface of the ring groove 51 to be created. The air flow enables a large portion of the polishing liquid retained in the ring groove 51 to be discharged toward the exterior of the retainer ring 32 before reaching the pad-outer-peripheral-side polishing region, and as a result, the amount of polishing liquid reaching the pad-outer-peripheral-side polishing region can be reduced. In this manner, the uneven structure 60 serves as the barrier that prevents the polishing liquid from reaching the pad-outer-peripheral-side polishing region (see the thick line in FIG. 3) of the polishing head 7.

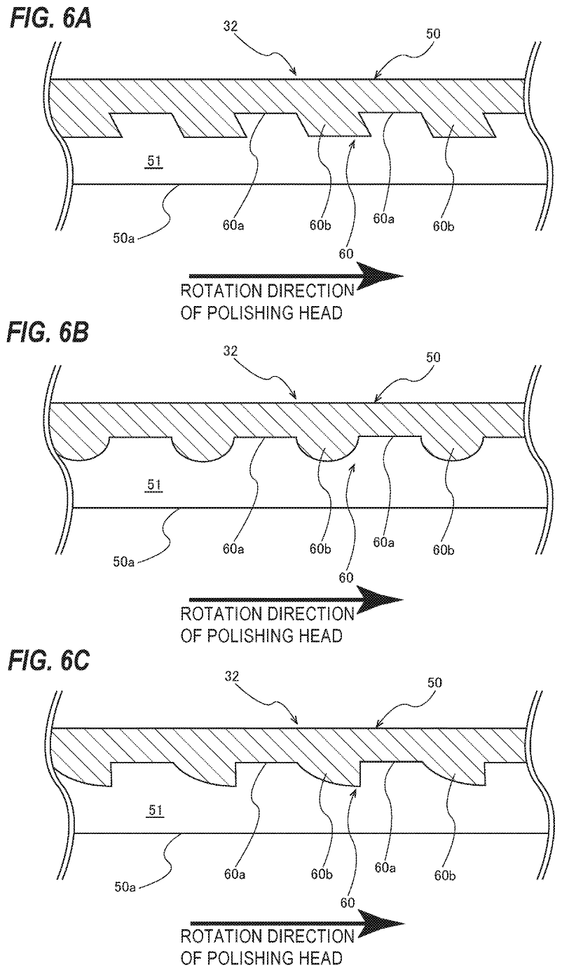

FIGS. 6A to 6C are exploded views each showing a modified example of the uneven structure. In the uneven structure 60 shown in FIG. 6A, the vertical cross-section of the convex portion 60b is inclined in a rotation direction of the polishing head 7 when viewed horizontally. According to this configuration, an increase in the air flow created in the ring groove 51 can be intended.

The convex portion 60b of the uneven structure 60 shown in FIG. 6B has the vertical cross section having an approximately semicircular shape. The convex portion 60b of the uneven structure 60 shown in FIG. 6C has the vertical cross-section having an approximately quarter-circle shape. When the convex portion 60b has the vertical cross-section including such an arc, the polishing liquid adhering to the convex portion 60b immediately falls from the convex portion 60b. Therefore, solidification of the abrasive contained in the polishing liquid, which adheres to the convex portion 60b, is prevented, so that solidified particles that has fallen from the convex portion 60b can be prevented from damaging the wafer W.

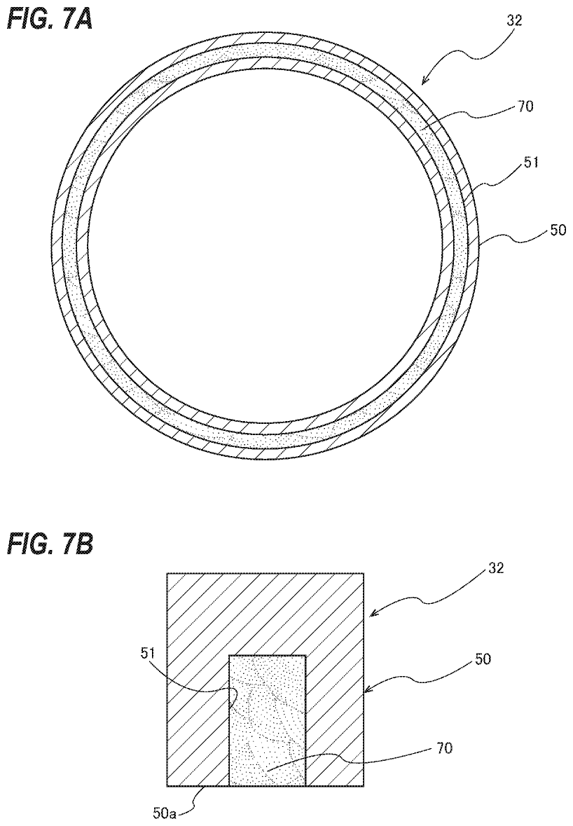

FIG. 7A is a horizontal cross-sectional view schematically showing the retainer ring according to still another embodiment, and FIG. 7B is a vertical cross-sectional view schematically showing the retainer ring shown in FIG. 7A. Configurations of this embodiment, which will not be particularly described, are the same as those of the embodiments described with reference to FIGS. 4A and 4B, and redundant descriptions thereof will be omitted.

In the embodiments shown in FIG. 7A and FIG. 7B, the retainer ring 32 has an adsorption agent 70 disposed in the ring groove 51 as the barrier, instead of the scraper 55. The adsorption agent 70 is composed of a material capable of adsorbing the polishing liquid. Examples of the material composing the adsorption agent 70 may include a porous material, such as polymer material, foaming agent, and nonwoven fabric. The adsorption agent 70 is held in the ring groove 51 using a holding means such as an adhesion agent. The adsorption agent 70 preferably has hardness equal to or softer than hardness of the material constituting the retainer ring 32.

The adsorption agent 70 can absorb the polishing liquid retained in the ring groove 51, thereby reducing the amount of polishing liquid reaching the pad-outer-peripheral-side polishing region. When the adsorption agent 70 absorbs the polishing liquid and reaches a saturated state, the adsorption agent 70 that has absorbed the polishing liquid is worked as a strong barrier that prevents further polishing liquid from entering the ring groove 51. Alternatively, the adsorption agent 70 that has reached the saturated state may be worked as a barrier that exchanges the polishing liquid reached the adsorption agent 70 with a part of the polishing liquid held by the adsorption agent itself, and thereby prevents the polishing liquid from entering the ring groove 51. In other words, the adsorption agent 70 serves as the barrier that prevents the polishing liquid from reaching the pad-outer-peripheral-side polishing region (see the thick line in FIG. 3) of the polishing head 7. With this configuration also, it is possible to reduce the amount of polishing liquid reaching the pad-outer-peripheral-side polishing region.

In the embodiments described above, the ring body 50 has one ring groove 51, but the number of ring grooves 51 is not limited to these embodiments. More specifically, the ring body 50 has at least one ring groove 51 formed in the lower surface of the ring body 50 and extending concentrically with the ring body 50.

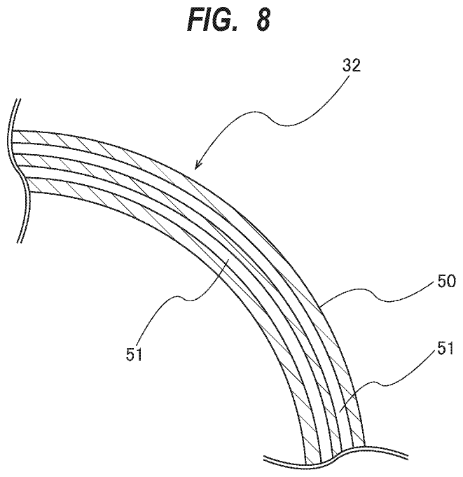

FIG. 8 is a horizontal cross-sectional view schematically showing a part of the retainer ring according to still another embodiment. The retainer ring 32 shown in FIG. 8 has a plurality of (two in the illustrated example) ring grooves 51. Each of the ring grooves 51 is provided with any one of the scraper 55 described above (see FIGS. 4A and 4B), the uneven structure 60 described above (see FIGS. 5A, 5B, and 6A to 6C), and the adsorption agent 70 described above (see FIGS. 7A and 7B) as the barrier.

In one embodiment, any one or several of the plurality of ring grooves 51 may be provided with the scraper 55 described above, the uneven structure 60 described above, and the adsorption agent 70 described above as a barrier. In this case, the remaining ring grooves 51 need not be provided with the barrier.

In this manner, the plurality of ring grooves 51 are provided, and the barriers are disposed in some or all of the plurality of ring grooves 51, thereby enabling the polishing liquid reaching the outer-peripheral-side polishing region to be regulated to the desired amount. As a result, the polishing rate over the entire surface of the wafer W can be controlled more precisely.

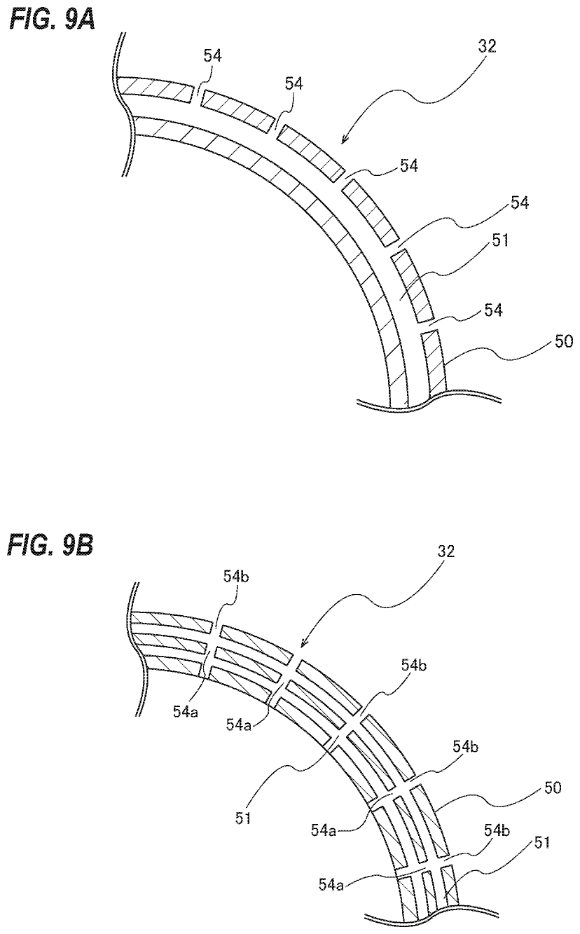

FIG. 9A is a horizontal cross-sectional view schematically showing a modified example of the retainer ring shown in FIG. 4A, and FIG. 9B is a horizontal cross-sectional view schematically showing a part of a modified example of the retainer ring shown in FIG. 8. As shown in FIG. 9A, the retainer ring 32 may have at least one lateral groove 54 extending from the ring groove 51 (outer circumferential surface thereof) to the outer circumferential surface of the ring body 50 in the retainer ring 32. The lateral groove 54 allows the ring groove 51 to communicate with the exterior of the retainer ring 32. Therefore, provision of the lateral groove 54 makes it possible to more easily discharge the polishing liquid retained in the ring groove 51 to the exterior of the retainer ring 32. Although the lateral grooves 54 shown in FIG. 9A extend in the radial direction of the retainer ring 32, the lateral grooves 54 may be inclined in the rotational direction of the retainer ring 32 when viewed horizontally.

As shown in FIG. 9B, when the retainer ring 32 has the plurality of ring grooves 51, the lateral grooves 54 may be constituted of first lateral grooves 54a connecting the adjacent ring grooves 51 to each other, and second lateral grooves 54b extending from the outermost ring groove 51 to the outer circumferential surface of the retainer ring 32. In one embodiment, the retainer ring 32 may have only the second lateral grooves 54b while omitting the first lateral grooves 54 shown in FIG. 9B. Further, although the second lateral grooves 54b shown in FIG. 9B are aligned with the first lateral grooves 54a, the second lateral grooves 54b may be offset in the circumferential direction of the retainer ring 32 with respect to the first lateral grooves 54a. Provision of the first lateral grooves 54a and the second lateral grooves 54b makes it possible to more easily discharge the polishing liquid retained in the plurality of ring grooves 51 to the exterior of the retainer ring 32.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

What is claimed is:

1. A retainer ring for use in a substrate holder for pressing a substrate against a polishing pad supplied with a polishing liquid to polish the substrate, comprising:
a ring body having a ring shape and supporting an outer periphery of the substrate pressed against the polishing pad;
wherein the ring body includes:
at least one ring groove formed in a lower surface to be pressed against the polishing pad, and extending concentrically with the ring body, and
a barrier configured to prevent the polishing liquid from reaching an interior from an exterior of the ring body.

2. The retainer ring according to claim 1, wherein the barrier is a scraper disposed in the ring groove, and
the scraper has a tip end which comes into contact with or is close to the polishing pad when the substrate is polished, and causes the polishing liquid retained in the ring groove to be discharged to an exterior of the retainer ring.

3. The retainer ring according to claim 1, wherein the barrier is an uneven structure formed in the ring groove, and
the uneven structure causes air flow from an inner circumferential surface toward an outer circumferential surface of the ring groove.

4. The retainer ring according to claim 1, wherein the barrier is an adsorption agent which is disposed in the ring groove, and is capable to absorb the polishing liquid.

5. The retainer ring according to claim 1, wherein the ring groove comprises a plurality of ring grooves, and
the barrier is provided in at least one of the plurality of ring grooves.

6. The retainer ring according to claim 1, further comprising at least one lateral groove extending from the ring groove to an outer circumferential surface of the ring body.

7. A substrate holder comprising:
a head body configured to hold a substrate, and press the substrate against a polishing pad to polish the substrate; and
a retainer ring according to any one of claims 1 to 6, the retainer ring being arranged so as to surround the substrate held in the head body.
